(19) United States
(12) Patent Application Publication
(10) Pub. No.: US 2014/0192588 A1
(43) Pub. Date: Jul. 10, 2014

(54) Nonvolatile Memory Device and Read Method Thereof

(71) Applicant: Samsung Electronics Co., Ltd., Suwon-si (KR)

(72) Inventors: Sungyeon Lee, Seoul (KR); Yeongtaek Lee, Seoul (KR); Kiwon Lim, Suwon-si (KR); Wonryul Chung, Hwaseong-si (KR)

(21) Appl. No.: 14/146,748

(22) Filed: Jan. 3, 2014

(30) Foreign Application Priority Data
Jan. 10, 2013 (KR) 10-2013-0003065

(51) Int. Cl. G11C 13/00

(52) U.S. Cl. CPC G11C 13/004
USPC 365/148

(57) ABSTRACT

A nonvolatile memory device is provided which includes a main area including main cells connected to word lines and main bit lines; a reference area including reference cells connected to the word lines and reference bit lines and programmed using the same write condition as that of the main area; a reference sense amplifier circuit configured to read data written at the reference area through the reference bit lines at a read operation; and control logic configured to control the reference sense amplifier circuit such that data written at the reference area is shifted with a weight scheme and then read, the data written at the reference area being used as a read reference value of the main area at a read operation.

### CROSS-REFERENCE TO RELATED APPLICATIONS

This application claims priority under 35 U.S.C. §119 to Korean Patent Application No. 10-2013-0003065 filed Jan. 10, 2013, in the Korean Intellectual Property Office, the entire disclosure of which is incorporated herein by reference.

### BACKGROUND

The inventive concepts described herein relate to nonvolatile memory devices and read methods thereof, and more particularly, relate to resistive memory devices including a resistive material and read methods thereof.

A demand for high-integration and mass random access memory devices may be increasing. A flash memory device used for handheld electronic devices may be typical of such a semiconductor memory device. Some semiconductor memory devices provide that capacitors of a DRAM that are replaced with a nonvolatile material. For example, such semiconductor memory devices may include a ferroelectric RAM (FRAM) using a ferroelectric capacitor, a magnetic RAM (MRAM) using a tunneling magneto-resistive (TRM) film, a phase change memory device using a chalcogenide alloy, and so on. In particular, the phase change memory device may be a nonvolatile memory device and implemented using a simple fabrication process. Also, the phase change memory device may be used to implement a mass memory with a low price.

A phase change memory cell may use a material whose characteristic is electrically changed between structured states respectively representing different electric read characteristics. For example, there may be known memory devices which are made of a chalcogenide material (hereinafter, referred to as “GST material”) being a germanium antimony telluride material (GST). The GST material may have an amorphous state representing a relatively high resistivity and a crystalline state representing a relatively low resistivity. That is, data values respectively corresponding to crystalline and amorphous states may be stored at the phase change memory cell by heating its GST material. The high resistivity and the low resistivity may indicate logic values ‘1’ and ‘0’ written, which are sensed by measuring a resistivity of the GST material. For this reason, the phase change memory device may be called a variable resistance memory device.

### SUMMARY

One aspect of embodiments of the inventive concept is directed to providing a nonvolatile memory device comprising a main area including main cells connected to word lines and main bit lines; a reference area including reference cells connected to the word lines and reference bit lines and programmed using the same write condition as that of the main area; a reference sense amplifier circuit configured to read data written at the reference area through the reference bit lines at a read operation; and control logic configured to control the reference sense amplifier circuit such that data written at the reference area is shifted with a weight scheme and then read, the data written at the reference area being used as a read reference value of the main area at a read operation.

In some embodiments, the reference area is programmed using the same verification voltage as that of the main area.

In some embodiments, the reference area is programmed at the same time as the main area.

In some embodiments, the control logic adjusts a level of a compensation current provided to the reference sense amplifier circuit and controls the reference sense amplifier circuit such that data written at the reference area is read with a weighting scheme.

In some embodiments, the control logic adjusts a level of a clamp voltage provided to the reference sense amplifier circuit and controls the reference sense amplifier circuit such that data written at the reference area is read with a weighting scheme.

Another aspect of embodiments of the inventive concept is directed to provide a nonvolatile memory device comprising a main area including a first main cell programmed to have a first resistance level corresponding to first data and a second main cell programmed to have a second resistance level corresponding to second data; a reference area including a reference cell programmed to have the first resistance level; a reference sense amplifier circuit configured to read a resistance value of the reference cell under a first read condition at a read operation and to generate a reference voltage based on the resistance value of the reference cell read; and a main sense amplifier circuit configured to read data stored at the first and second main cells using the reference voltage under a second read condition different from the first read condition, wherein the first and second main cells and the reference cell share the same word line.

In some embodiments, the resistance value of the reference cell read has a value between resistance values of the first and second main cells.

In some embodiments, a resistance value of the reference cell read under the first read condition is shifted with a weight varied in response to a size of the first resistance level and the shifted resistance value is then read.

In some embodiments, the weight is varied according to a time elapsing from a program operation on the reference cell.

In some embodiments, a resistance value of the reference cell read under the first read condition is shifted over a margin and the shifted resistance value is then read.

Still another aspect of embodiments of the inventive concept is directed to provide a read method of a nonvolatile memory device which a main area including main cells connected to word lines and main bit lines; and a reference area including reference cells connected to the word lines and reference bit lines and programmed using the same write condition as that of the main area, the read method comprising shifting data stored at the reference area with a weighting scheme to read the shifted data; generating a reference value based on the read data; and reading data stored at the main area using the reference voltage.

In some embodiments, the reference area is programmed using the same verification voltage as that of the main area.

In some embodiments, the reference area is programmed at the same time with the main area.

In some embodiments, a weight applied to shift data stored at the reference area is varied according to a time elapsing from a program operation on the reference cell.

In some embodiments, the weight is varied in response to data stored at the reference area.

Some embodiments of the present inventive concept are directed to nonvolatile memory devices including a main area including main cells that are connected to word lines and main bit lines and a reference area including reference cells that are connected to the word lines and reference bit lines and that are programmed using a same write condition as the main cells. Control logic may be configured to cause data written in the reference cells to be shifted by a weight and then read and to cause data read from the main cells to be read using the data read from the reference cells as a read reference value for the main cells.

In some embodiments, the reference area is programmed using a same verification voltage as that of the main area and the reference area is programmed at a same time as the main area.

Some embodiments further include a reference sense amplifier circuit configured to read data written at the reference area through the reference bit lines at a read operation. In some embodiments, the control logic is configured to adjust a level of a compensation current provided to the reference sense amplifier circuit and to control the reference sense amplifier circuit such that data written at the reference area is read with a weighting scheme. Some embodiments provide that the control logic is configured to adjust a level of a clamp voltage provided to the reference sense amplifier circuit and to control the reference sense amplifier circuit such that data written at the reference area is read with a weighting scheme.

It is noted that aspects of the inventive concept described with respect to one embodiment, may be incorporated in a different embodiment although not specifically described relative thereto. That is, all embodiments and/or features of any embodiment can be combined in any way and/or combination. These and other objects and/or aspects of the present inventive concept are explained in detail in the specification set forth below.

### BRIEF DESCRIPTION OF THE FIGURES

The accompanying figures are included to provide a further understanding of the present invention, and are incorporated in and constitute a part of this specification. The drawings illustrate some embodiments of the present invention and, together with the description, serve to explain principles of the present invention.

FIG. 1 is a block diagram schematically illustrating a nonvolatile memory device according to some embodiments of the inventive concept.

FIG. 2 is a diagram schematically illustrating a memory cell array according to some embodiments of the inventive concept,

FIG. 3 is a diagram schematically illustrating a memory cell array according to some embodiments of the inventive concept.

FIG. 4 is a diagram a resistance distribution just after a write operation of memory cells in a memory cell array of FIG. 1.

FIG. 5 is a diagram schematically illustrating a resistance distribution of memory cells of a memory cell array of FIG. 1 after a time elapses.

FIG. 6 is a graph schematically illustrating a resistance value of a memory cell varied by lapse of time.

FIG. 7 is a block diagram schematically illustrating a nonvolatile memory device according to some embodiments of the inventive concept.

FIG. 8 is a graph schematically illustrating write and read operations on a reference area according to some embodiments of the inventive concept.

FIG. 9 is a graph schematically illustrating write and read operations on a reference area according to some embodiments of the inventive concept.

FIG. 10 is a graph schematically illustrating resistance values of main and reference cells varied by lapse of time.

FIG. 11 is a block diagram schematically illustrating a nonvolatile memory device according to some embodiments of the inventive concept.

FIG. 12 is a flow chart schematically illustrating a read method of a nonvolatile memory device according to some embodiments of the inventive concept.

FIG. 13 is a block diagram schematically illustrating a handheld electronic system to which a phase change memory device according to some embodiments of the inventive concept is applied.

FIG. 14 is a block diagram schematically illustrating a memory card including a nonvolatile memory device according to some embodiments of the inventive concept.

FIG. 15 is a diagram schematically illustrating various systems to which a memory card in FIG. 14 is applied.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Reference numerals are indicated in detail in some embodiments of the present inventive concept, and their examples are represented in reference drawings. Throughout the drawings, like reference numerals are used for referring to the same or similar elements in the description and drawings.

It is well understood that embodiments of the inventive concept are applicable to all nonvolatile memory devices, using a resistive material, such as a resistive RAM (RRAM), a magnetic RAM (MRAM), and so on.

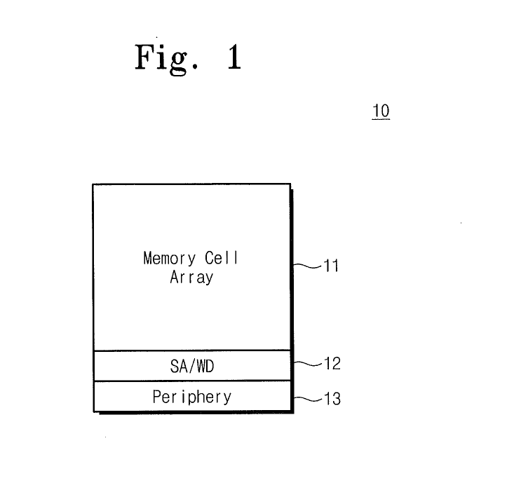

FIG. 1 is a block diagram schematically illustrating a nonvolatile memory device. Referring to FIG. 1, a nonvolatile memory device 10 may include a memory cell array 11, a sense amplifier/write driver block 12, and a periphery area 13.

The memory cell array 11 may include multiple nonvolatile memory devices, each of which has a switching element and a resistive element. The switching element may be formed of various elements such as a MOS transistor, and/or a diode, among others. The resistive element may be formed to include a phase change film made of a GST material.

The sense amplifier/write driver block 12 may perform write and read operations on the memory cell array 11. The periphery area 13 may include a column selector, a row selector, a voltage generator, and/or logic circuit blocks for working the sense amplifier/write driver block 12.

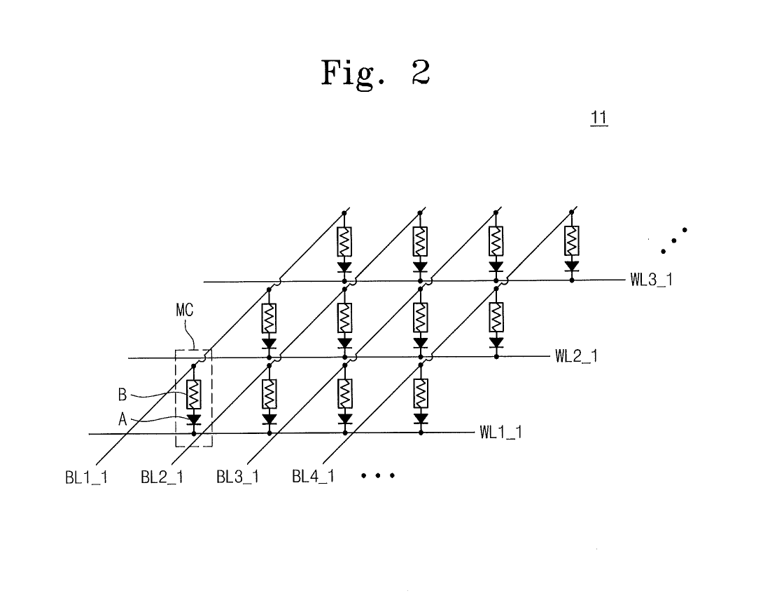

FIG. 2 is a diagram schematically illustrating a memory cell array according to some embodiments of the inventive concept. Referring to FIG. 2, a memory cell array 11 may have a cross point structure. The cross point structure may mean such a structure that a memory cell is formed at an intersection of two different lines.

For example, resistive memory cells MC may be formed at intersections of bit lines BL1_1 to BL4_1 and word lines WL1_1˜WL31. The bit lines BL1_1 to BL4_1 may extend in a first direction and the word lines WL1_1˜WL3_1 may extend in a second direction crossing the first direction.

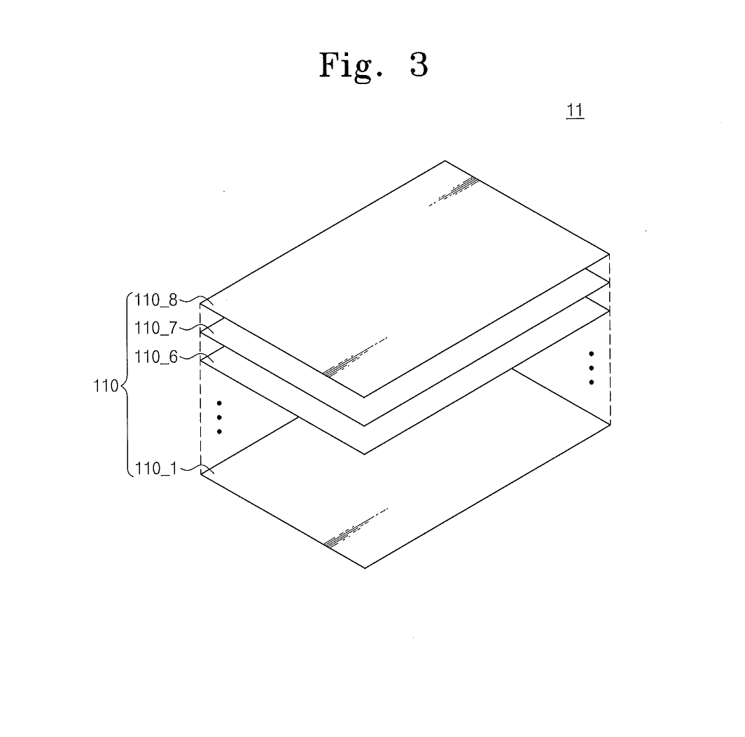

FIG. 3 is a diagram schematically illustrating a memory cell array according to some embodiments of the inventive concept. Referring to FIG. 3, a memory cell array 11 may have a three-dimensional stack structure where multiple memory cell layers 110_1 to 110_8 are stacked in a vertical direction. In FIG. 3, there is illustrated an example where eight memory cell layers 110_1 to 110_8 are stacked. However, the inventive concept is not limited thereto.

Each of the memory cell layers 110_1 to 110_8 may include multiple memory cell groups and/or multiple redundancy memory cell groups. In the event that a memory cell array has a three-dimensional stack structure, each of the memory cell layers 110_1 to 110_8 may have a cross point structure illustrated in FIG. 2. However, the inventive concept is not limited thereto.

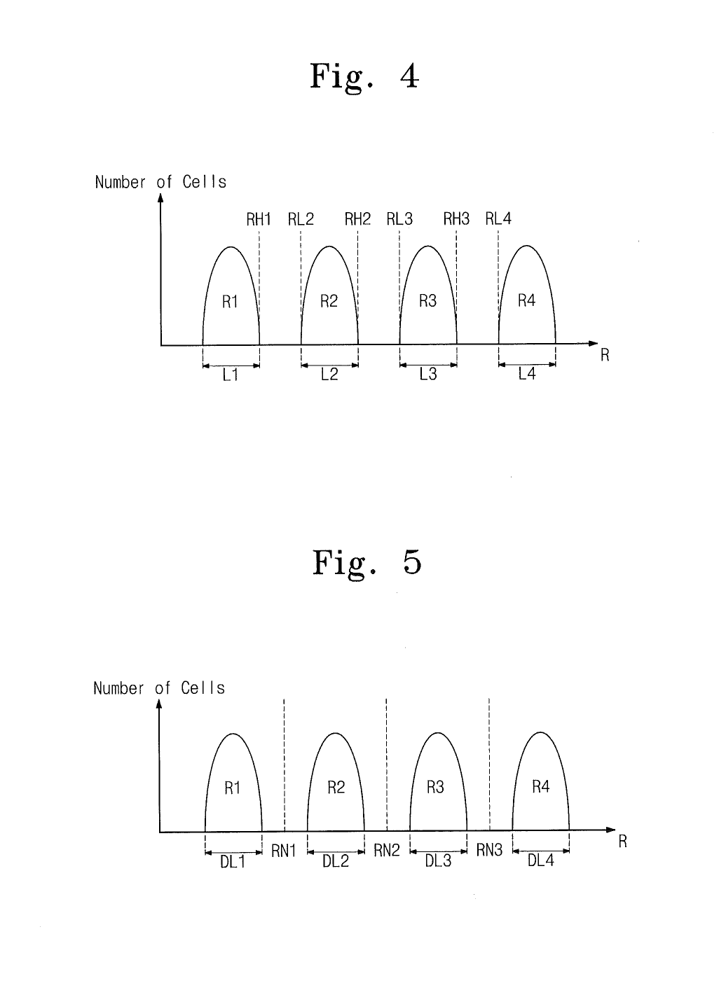

A resistance value of a resistive element included in each memory cell of a memory cell array may be increased due to various causes over time. This is more fully described below with reference to FIGS. 4 to 6.

FIG. 4 is a diagram a resistance distribution just after a write operation of memory cells in a memory cell array of FIG. 1. Referring to FIG, 4, a resistive memory cell may be a multi-bit cell. In some embodiments, a resistive memory cell may store one of first to fourth data R1 to R4.

The first to fourth data R1 to R4 may correspond to first to fourth resistance levels L1 to L4, respectively. Resistance values of the first to fourth resistance levels L1 to L4 may be sequentially increased. For example, the first resistance level L1 may be lower than RH1, the second resistance level L2 may be higher than RL2 and lower than RH2, the third resistance level L3 may be higher than RL3 and lower than RH3, and the fourth resistance level L4 may be higher than RL4. The RL2, RL3, RL4, RH1, RH2, and RH3 may be verification voltages used at a verification read operation for checking whether data is accurately written at a write operation.

FIG. 5 is a diagram schematically illustrating a resistance distribution of memory cells of a memory cell array of FIG. 1 after a time elapses. A resistance value of a resistive element may be increased due to various causes over time. In particular, in the event that an initial resistance value of a resistive element is large, a resistance value of a reset state may be substantially increased as a time elapses. This may be referred to as a resistance drift.

First to fourth data R1 to R4 may correspond to first to fourth resistance levels DL1 to DL4, respectively. With the resistance drift, first to fourth resistance levels DL1 to DL4 of FIG. 5 may be wider than first to fourth resistance levels L1 to L4 of FIG. 4. In some embodiments, an average value of the first to fourth resistance levels DL1 to DL4 of FIG. 5 may be larger than that of the first to fourth resistance levels L1 to L4 of FIG. 4.

‘RN1’ may be a resistance value between the first resistance level DL1 and the second resistance level DL2, ‘RN2’ may be a resistance value between the second resistance level DL2 and the third resistance level DL3, and ‘RN3’ may be a resistance value between the third resistance level DL1 and the fourth resistance level DL4. Here, RN1 to RN3 may be read reference values used at a normal read operation. For example, a resistive memory cell having a resistance value smaller than RN1 may be determined to be a memory cell storing the first data R1.

Since a voltage level corresponding to each data may vary by lapse of time, a reference read value used at a normal read operation may be varied to read data with a lower error occurrence.

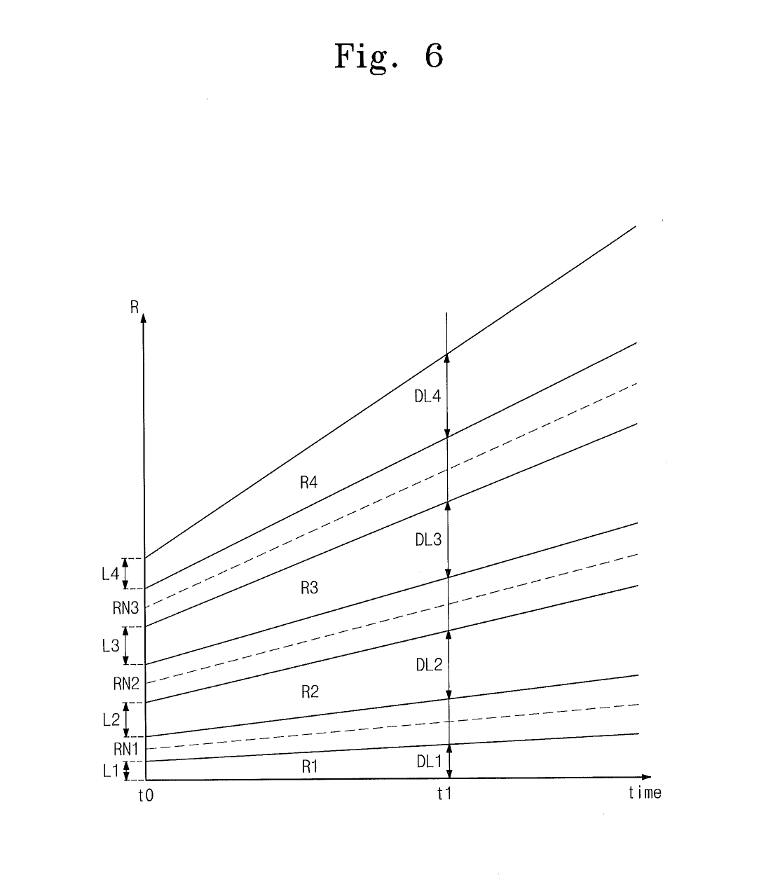

FIG. 6 is a graph schematically illustrating a resistance value of a memory cell varied by lapse of time. Referring to FIG. 6, first to fourth data R1 to R4 just after a write operation (t0) may correspond to first to fourth resistance levels L1 to L4, respectively. After a time elapses, that is, at t1, the first to fourth data R1 to R4 may correspond to first to fourth resistance levels DL1 to DL4, respectively.

As illustrated in FIG. 6, a resistance value of a memory cell may be varied by lapse of time. If a fixed read reference value is used at a normal read operation, a read error may be generated. A reference cell being the same resistive element as a memory cell may be used to vary a read reference value in response to a variation in resistance of the memory cell.

When a write operation of a memory cell is performed, a data write operation corresponding to a read reference value may be also performed with respect to a reference cell. Since a resistance value of the reference cell may be varied by a resistance drift, a resistance value of the reference cell may be used as a read reference value for a normal read operation of a memory cell regardless of lapse of time. A memory cell and a reference cell may be simultaneously written to reduce an error due to a write time difference of the memory cell and the reference cell. Below, a nonvolatile memory device including a reference cell will be more fully described with reference to accompanying drawings.

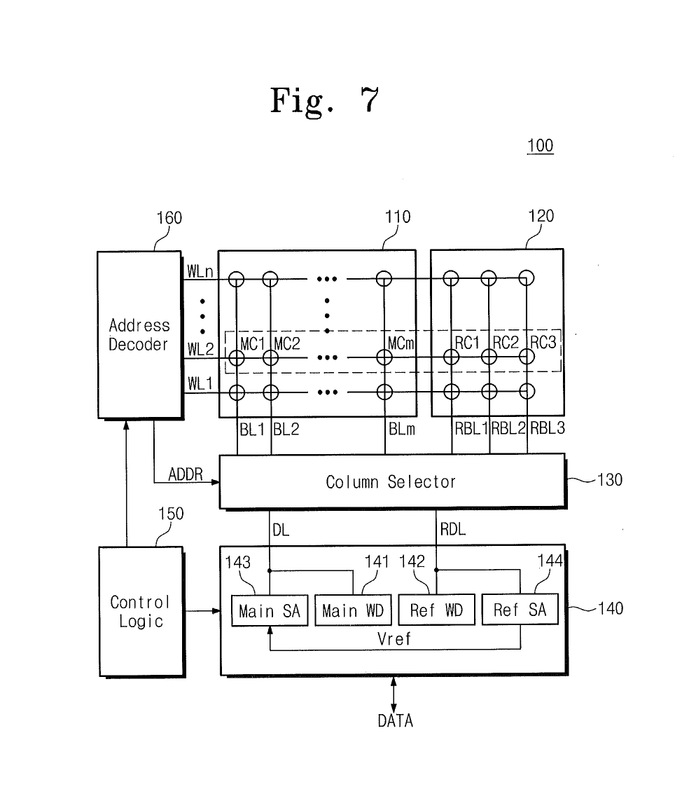

FIG. 7 is a block diagram schematically illustrating a nonvolatile memory device according to some embodiments of the inventive concept. Referring to FIG. 7, a nonvolatile memory device 100 may include a main area 110, a reference area 120, a column selector 130, an input/output circuit 140, control logic 150, and/or an address decoder 160.

The nonvolatile memory device 100 may correct an error due to a resistance drift of data stored at the main area 110 based on the reference area 120 that is written using the same write condition as that of the main area 110.

To correct an error, the nonvolatile memory device 100 may read a resistance value of the reference area 120 with a weight. The nonvolatile memory device 100 may generate reference values for deciding states of data stored at the main area 110 using a reference value of the reference area 120 read with a weight.

Some embodiments provide that the main area 110 may include multiple main cells, which are connected with multiple word lines WL1 to WLn and multiple bit lines BL1 to BLn. The reference area 120 may include multiple reference cells, which are connected with the word lines WL1 to WLn and multiple bit lines RBL1 to RBL3. The main and reference cells may be phase change memory cells, each storing multi-bit data,

The main area 110 and the reference area 120 may share the word lines WL1 to WLn. As described with reference to FIGS. 2 and 3, memory cells of the main and reference areas 110 and 120, that is, main and reference cells, may be formed of a switching element and a resistive element. The switching element may be implemented by various elements such as a MOS transistor and/or a diode, among others. The resistive element may be formed to include a phase change film made of a GST material.

The input/output circuit may include a main write driver 141, a reference write driver 142, a main sense amplifier circuit 143, and a reference sense amplifier circuit 144.

The main write driver 141 may be controlled by the control logic 150, and may supply a write current to bit lines of main cells according to data provided from an external device. The main write driver 141 may be connected to the main area 110 through main data lines DL.

The reference write driver 142 may be controlled by the control logic 150, and may supply a write current to bit lines of reference cells according to data provided from an external device. The reference write driver 142 may be connected to the reference area 110 through reference data lines RDL.

At a write operation, the main and reference write drivers 141 and 142 may program reference cells sharing a word line with selected memory cells using the same write condition as that of the main area 110 whenever a pulse current for programming the selected memory cells of the main area 110 is applied. For example, at a write operation, the main and reference write drivers 141 and 142 may simultaneously program reference cells connected to a selected word line using the same verification voltage as that of selected memory cells of the main area 110.

For example, assuming that a word line WL2 is selected, main cells MC 1 to MCm connected to the word line WL2 may be programmed to store one of first to fourth data.

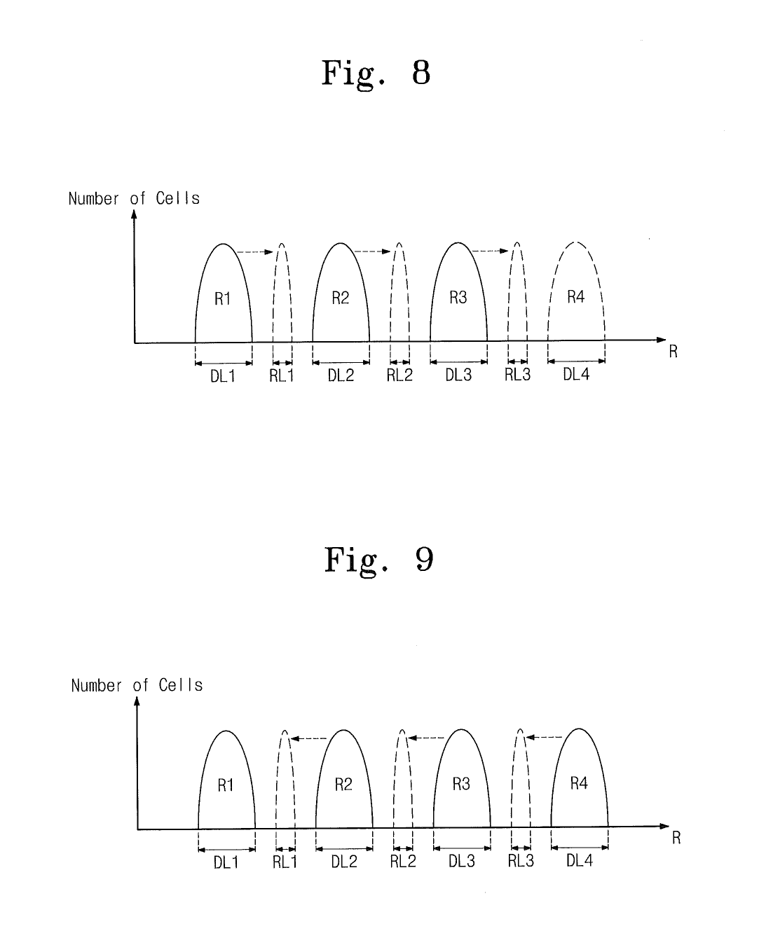

When the main cells MC1 to MCm are programmed, reference cells RC1 to RC3 connected to the word line WL2 may be programmed to store first to third data, respectively. Some embodiments provide that the reference cells RC1 to RC3 may be programmed to store second to fourth data. This will be more fully described with reference to FIGS. 8 and 9.

The number of reference cells connected with a word line may be decided based on the number of data bits stored at a main cell. For example, in the event that a main cell is a 2-bit cell storing one of first to fourth data, a word line may be connected with three reference cells. However, the inventive concept is not limited thereto.

The main sense amplifier circuit 143 may sense data of selected main cells at a read operation. The main sense amplifier circuit 143 may compare a reference voltage Vref with a voltage of a sensing node connected with a bit line of a selected main cell at a read operation. The main sense amplifier circuit 143 may output a comparison result as read data.

The main sense amplifier circuit 143 according to the inventive concept may be provided with the reference voltage Vref for compensating for a variation in a resistance value of a memory cell due to a resistance drift. The reference voltage Vref may be provided from the reference sense amplifier circuit 144.

The reference sense amplifier circuit 144 may drift and read data of reference cells by a weight in response to a control of the control logic 150. The reference sense amplifier circuit 144 may generate the reference voltage Vref for reading multi-level cells based on data of reference cells thus read.

The control logic 150 may control an operation of the input/output circuit 140 at a read operation and a write operation. At a read operation, the control logic 150 may control the reference sense amplifier circuit 144 such that data stored at the reference area 120 is read with data being shifted by a weight. As the control logic 150 adjusts a read condition of the reference sense amplifier circuit 144, resistance values of reference cells of the reference area 120 may be shifted and read.

For example, the control logic 150 may control a level of a compensation current of the reference sense amplifier circuit 144 such that resistance values of reference cells of the reference area 120 are shifted and read. In some embodiments, the control logic 150 may control a level of a clamp voltage of the reference sense amplifier circuit 144 such that resistance values of reference cells of the reference area 120 are shifted and read. However, the inventive concept is not limited thereto.

The address decoder 160 may decode an address provided from an external device at a write or read operation and provide the decoded result to selection circuits for selecting a word line and a bit line.

The nonvolatile memory device 100 may include main cells that store input/output data and reference cells corresponding to the main cells. Whenever the main cells are programmed, the reference cells may be programmed to have a specific state using the same verification voltage as that of main cells.

A degree of a resistance drift of GST materials of memory cells according to lapse of time of reference cells may be synchronized with that of the main cells. Thus, it is possible to correct an error due to a resistance drift of the main cells based on reference cells being synchronized therewith. Since reference cells of the nonvolatile memory cells 100 may be programmed using the same write condition as that of the main cells, a verification voltage and/or a write time may not be additionally required. This may provide an implementation with a simple control and a low level of complexity.

Reference cells of the nonvolatile memory device 100 may be read by the reference sense amplifier circuit 144 with data thereof being shifted by a weight. The nonvolatile memory device 100 may generate reference voltages for deciding states of data stored at the main area 110 using a resistance value of the reference area 120 thus read. The reference voltages may be used as read reference values at a normal read operation of the main area 110. This will be more fully described with reference to FIGS. 8 and 9.

FIG, 8 is a graph schematically illustrating write and read operations on a reference area according to some embodiments of the inventive concept. In FIG. 8, a horizontal axis may indicate a resistance value and a vertical axis may indicate the number of memory cells.

Referring to FIG. 8, each reference cell of a reference area 120 (refer FIG. 7) may be programmed to have resistance levels respectively corresponding to first to third data R1 to R3. After a time elapses, the first to third data R1 to R3 may correspond to first to third resistance levels DL1 to DL3, respectively.

At a normal read operation on main cells of a main area 110 (refer to FIG. 7), resistance levels of reference cells of the reference area 120 may be read as read reference values with them being shifted. Control logic 150 (refer to FIG, 7) may read reference cells of the reference area 120 with a weight using a reference sense amplifier circuit 144 (refer to FIG. 7). Under a control of the control logic 150, the reference cells of the reference area 120 may be read as reference levels corresponding to the first to third resistance levels RL1 to RL3, respectively.

FIG. 9 is a graph schematically illustrating write and read operations on a reference area according to some embodiments of the inventive concept. In FIG. 9, a horizontal axis may indicate a resistance value and a vertical axis may indicate the number of memory cells,

Referring to FIG. 9, each reference cell of a reference area 120 (refer FIG. 7) may be programmed to have resistance levels respectively corresponding to second to fourth data R2 to R4. After a time elapses, the second to fourth data R2 to R4 may correspond to second to fourth resistance levels DL2 to DL4, respectively.

At a normal read operation on main cells of a main area 110 (refer to FIG. 7), resistance levels of reference cells of the reference area 120 may be read as read reference values with them being shifted, Control logic 150 (refer to FIG. 7) may read reference cells of the reference area 120 with a weight using a reference sense amplifier circuit 144 (refer to FIG. 7). Under a control of the control logic 150, the reference cells of the reference area 120 may be read as reference levels corresponding to the first to third resistance levels RL1 to RL3, respectively.

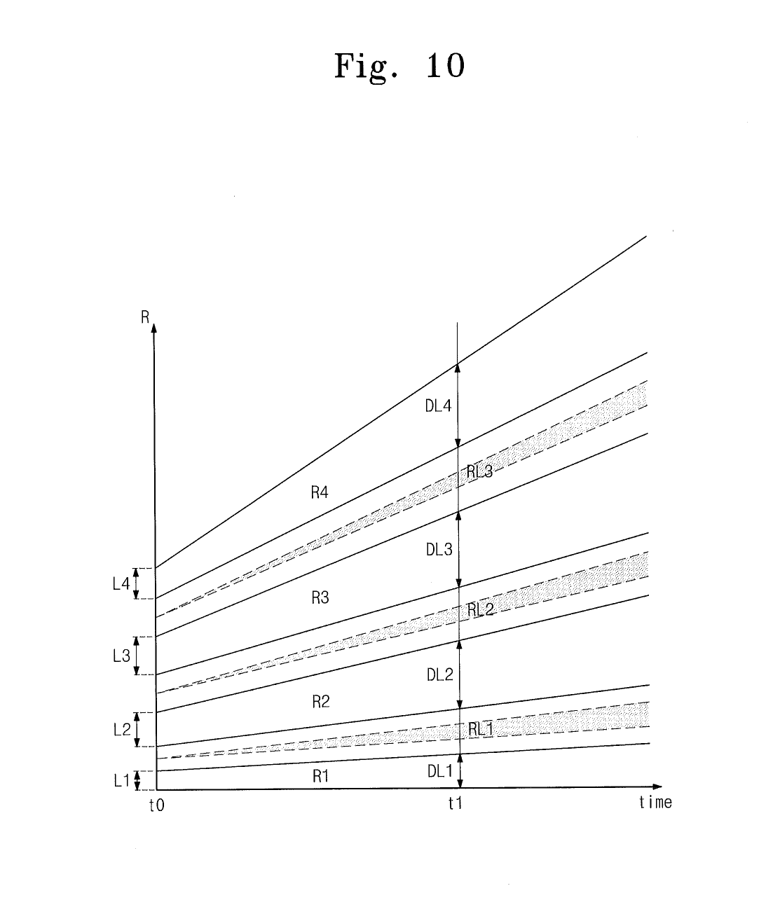

In FIGS. 8 and 9, shift levels of resistance values of reference cells may be changed according to a time and an initial resistance value. This will be more fully described with reference to FIG. 10.

FIG. 10 is a graph schematically illustrating resistance values of main and reference cells varied by lapse of time. Referring to FIG, 10, first to fourth data R1 to R4 just after a write operation (t0) may correspond to first to fourth resistance levels L1 to L4, respectively. After a time elapses, that is, at t1, the first to fourth data R1 to R4 may correspond to first to fourth resistance levels DL1 to DL4, respectively.

A shaded domain of FIG. 10 may be a domain of a read reference value where a predetermined sensing margin is secured, For a reliable operation, resistance values of reference cells may be read with them being shifted into the shaded domain.

As illustrated in FIG. 10, a degree of a resistance drift may be varied according to a time lapsing from a write point of time and an initial resistance value. Control logic 150 (refer to FIG. 7) may read resistance values of reference cells of a reference area 120 using a reference sense amplifier circuit 144 (refer to FIG. 7) with the resistance value being shifted into a shaded domain. Shift levels of resistance values of reference cells may be varied according to a time lapsing from a write point of time and/or an initial resistance value.

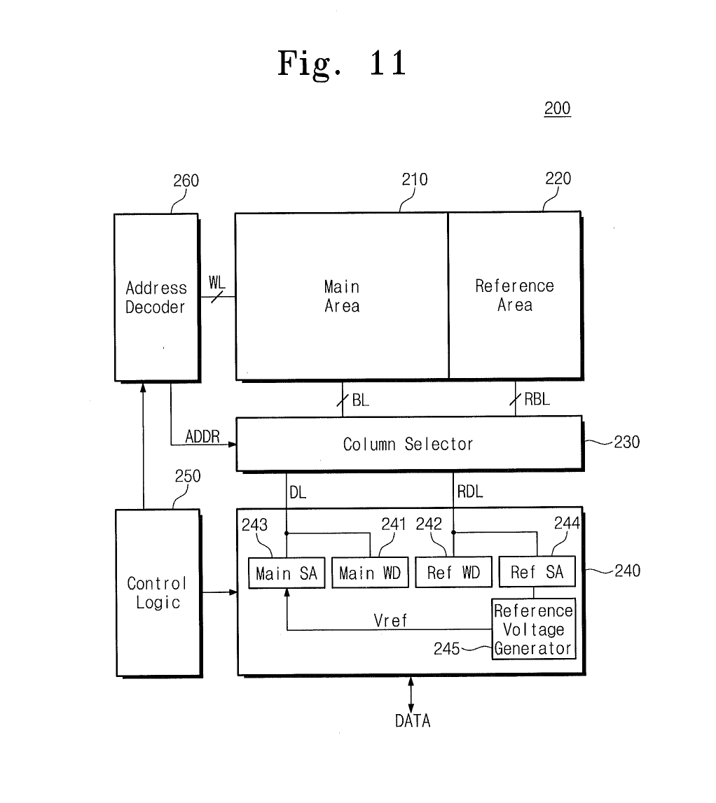

FIG. 11 is a block diagram schematically illustrating a nonvolatile memory device according to some embodiments of the inventive concept. Referring to FIG, 11, a nonvolatile memory device 200 may include a main area 210, a reference area 220, a column selector 230, an input/output circuit 240, control logic 250, and an address decoder 260. The main area 210, the reference area 220, the column selector 230, and/or the address decoder 260 may be configured substantially the same as a main area 110, a reference area 120, a column selector 130, and an address decoder 160 of FIG. 7.

The nonvolatile memory device 200 may correct an error due to a resistance drift of data stored at the main area 110 based on the reference area 220, which may be written using the same write condition as that of the main area 210.

To correct an error, the nonvolatile memory device 200 may read a resistance value of the reference area 220 and correct the read resistance value with a weight. The nonvolatile memory device 200 may generate read reference values for deciding states of data stored at the main area 210 using a reference value of the reference area 220 corrected with a weight.

A reference sense amplifier circuit 244 may sense resistance levels corresponding to data stored at reference cells at a read operation. The reference sense amplifier circuit 244 may provide the sensed reference levels to a reference voltage generator 245.

The reference voltage generator 245 may shift a resistance level provided from the reference sense amplifier circuit 244 to generate a reference voltage Vref corresponding to a shifted level. The reference voltage Vref may correspond to a resistance value of a shaded domain of FIG. 10. The reference voltage Vref may be a read reference value on the main area 210 at a normal read operation. Shifted levels of resistance levels of reference cells may be varied according to a time lapsing from a write point of time and an initial resistance value.

Since the nonvolatile memory device 200 generates reference voltages for deciding states of data stored at the main area 210 using shifted resistance levels of resistance levels of reference cells, an error due to a resistance drift may be reduced. Also, since the nonvolatile memory device 200 uses reference cells programmed using the same write condition as that of the main cells, a verification voltage or a write time may not be additionally required. This may provide an implementation with a simple control and a low level of complexity.

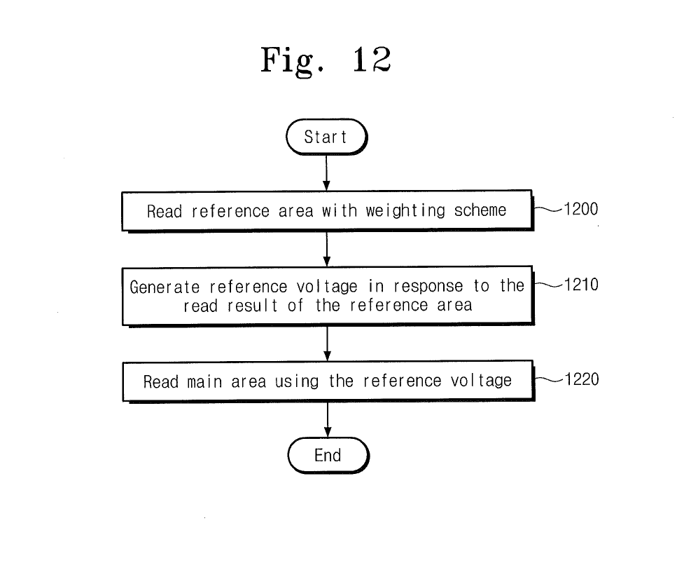

FIG. 12 is a flow chart schematically illustrating a read method of a nonvolatile memory device according to some embodiments of the inventive concept.

In operation 1200, a resistance value of a reference area may be read with a weighting scheme. The resistance value of the reference area may be a resistance level corresponding to each program state of a main area. The resistance value of the reference area may be read with it being shifted by a predetermined value. A shifted level of a resistance level of a reference cell may be varied according to a time lapsing from a write point of time and an initial resistance value.

Control logic may adjust a read condition of the reference area such that a resistance value of the reference area is shifted. For example, the control logic may control a level of a compensation current or a level of a clamp voltage of a reference sense amplifier circuit such that resistance values of reference cells of the reference area are shifted and read. However, the inventive concept is not limited thereto.

In operation 1210, reference voltages corresponding to resistance values of reference cells shifted and read may be generated.

In operation 1220, memory cells of a main area may be read using the reference voltages as read reference values.

With a read method of the inventive concept, since reference cells are programmed using the same write condition as that of main cells, a verification voltage or a write time may not be additionally required. This may provide an implementation with a simple control and a low level of complexity. Also, since resistance values of reference cells are shifted so as to be used as read reference values at a main cell read operation, an error due to a resistance drift may be corrected.

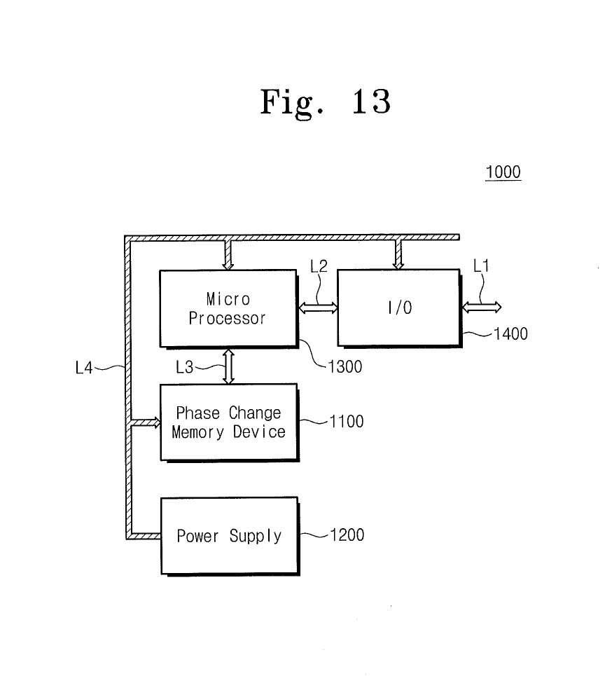

FIG. 13 is a block diagram schematically illustrating a handheld electronic system 1000 to which a phase change memory device according to some embodiments of the inventive concept is applied. A phase change memory device 1100 may include reference cells which are programmed using the same write condition as that of main cells. Since resistance values of reference cells are shifted so as to be used as read reference values at a main cell read operation, an error due to a resistance drift may be corrected.

The phase change memory device 1100 connected to a microprocessor 1300 through a bus line L3 may be used as a main memory of the handheld electronic system 1000. A power supply 1200 may supply a power to the microprocessor 1300, an input/output device 1400, and/or the phase change memory device 1100 through a power line L4. Some embodiments provide that the microprocessor 1300 and the input/output device 1400 may constitute a memory controller for controlling the phase change memory device 1100.

In the event that input data is provided to the input/output device 1400 through a line L1, the microprocessor 1300 may receive and process the input data through a line L2 to output the processed result to the phase change memory device 1100 through a bus line L3. The phase change memory device 1100 may store data provided through the bus line L3 at memory cells. Data stored at memory cells may be read by the microprocessor 1300, and the read data may be output to an external device through the input/output device 1400.

Although a power of the power supply 1200 is not supplied to the power line L4, data stored at the phase change memory device 1100 may be retained by virtue of a characteristic of a phase change material. The reason may be that the phase change memory device 1100 is a nonvolatile memory unlike a DRAM. The phase change memory device 1100 may be advantageous in terms of an operating speed and power consumption as compared to other memory devices.

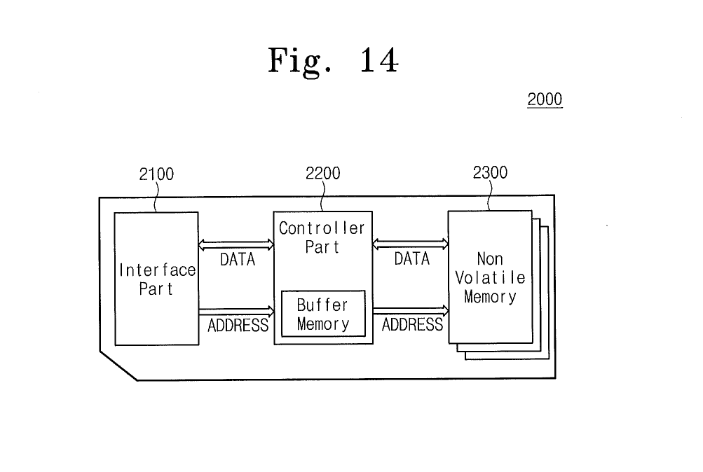

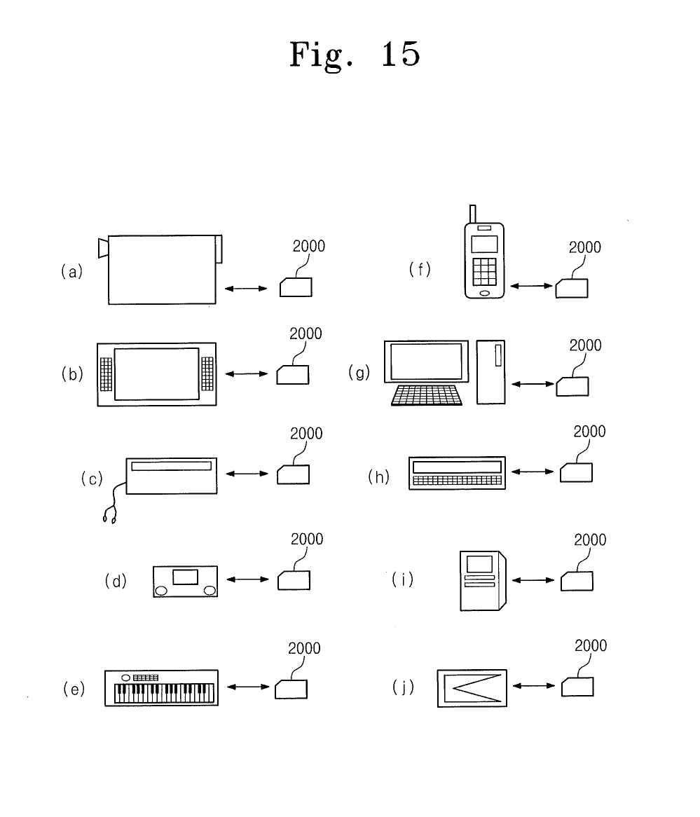

FIG. 14 is a block diagram schematically illustrating a memory card including a nonvolatile memory device according to some embodiments of the inventive concept. A memory card 2000, for example, may be an MMC card, an SD card, a multiuse card, a micro-SD card, a memory stick, a compact SD card, an ID card, a PCMCIA card, an SSD card, a chip-card, a smartcard, and/or an USB card, among others,

Referring to FIG, 14, the memory card 2000 may include an interface circuit 2100 for interfacing with an external device, a controller 2200 including a buffer memory and controlling an operation of the memory card 2000, and at least one nonvolatile memory device 2300 according to some embodiments of the inventive concept. The controller 2200 may be a processor which is configured to control write and read operations of the nonvolatile memory device 2300. The controller 2200 may be coupled with the nonvolatile memory device 2300 and the interface circuit 2100 via a data bus and/or an address bus.

The nonvolatile memory device 2300 may include reference cells that are programmed using the same write condition as that of main cells. Since resistance values of reference cells are shifted so as to be used as read reference values at a main cell read operation, an error due to a resistance drift may be corrected.

FIG, 15 is a diagram schematically illustrating various systems to which a memory card in FIG. 14 is applied. Referring to FIG. 15, a memory card 2000 may be applied to a video camera (a), a television (b), an audio device (c), a game machine (d), an electronic music device (e), a cellular phone (f), a computer (g), a Personal Digital Assistant (h), a voice recorder (i), and/or a PC card (j), among others,

A nonvolatile memory device according to some embodiments of the inventive concept may be packed using various types of packages. For example, a non-volatile memory device or a memory controller according to the inventive concept may be packed using packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and/or Wafer-Level Processed Stack Package (WSP), among others.

The inventive concept may be modified or changed variously. For example, detailed structures of a main area, a reference area, a write driver, a main sense amplifier circuit, and/or a reference sense amplifier circuit may be changed or modified variously according to an environment and/or use. While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A nonvolatile memory device, comprising:
a main area including main cells connected to word lines and main bit lines;
a reference area including reference cells connected to the word lines and reference bit lines and programmed using a same write condition as that of the main area; and
control logic configured to cause data written at the reference area is shifted with a weighting scheme and then read, the data written at the reference area being used as a read reference value of the main area at a read operation.

2. The nonvolatile memory device of claim 1, further comprising a reference sense amplifier circuit configured to read data written at the reference area through the reference bit lines at a read operation.

3. The nonvolatile memory device of claim 2, wherein the reference area is programmed using a same verification voltage as that of the main area,

4. The nonvolatile memory device of claim 2, wherein the reference area is programmed at a same time as the main area.

5. The nonvolatile memory device of claim 2, wherein the control logic is configured to adjust a level of a compensation current provided to the reference sense amplifier circuit and to control the reference sense amplifier circuit such that data written at the reference area is read with the weighting scheme.

6. The nonvolatile memory device of claim 2, wherein the control logic is configured to adjust a level of a clamp voltage provided to the reference sense amplifier circuit and to control the reference sense amplifier circuit such that data written at the reference area is read with the weighting scheme.

7. A nonvolatile memory device, comprising:
a main area including a first main cell programmed to have a first resistance level corresponding to first data and a second main cell programmed to have a second resistance level corresponding to second data;
a reference area including a reference cell programmed to have the first resistance level;
a reference sense amplifier circuit configured to read a resistance value of the reference cell under a first read condition at a read operation and to generate a reference voltage based on the resistance value of the reference cell read; and
a main sense amplifier circuit configured to read data stored at the first and second main cells using the reference voltage under a second read condition that is different from the first read condition,
wherein the first and second main cells and the reference cell share a same word line.

8. The nonvolatile memory device of claim 7, wherein the resistance value of the reference cell read has a value between resistance values of the first and second main cells.

9. The nonvolatile memory device of claim 8, wherein the resistance value of the reference cell read under the first read condition is shifted with a weight that is varied in response to a size of the first resistance level and the shifted resistance value is then read.

10. The nonvolatile memory device of claim 9, wherein the weight is varied according to a time elapsing from a program operation on the reference cell.

12. The nonvolatile memory device of claim 10, wherein the resistance value of the reference cell read under the first read condition is shifted over a margin and the shifted resistance value is then read.

12. A read method of a nonvolatile memory device including a main area including main cells connected to word lines and main bit lines; and a reference area including reference cells connected to the word lines and reference bit lines and programmed using a same write condition as that of the main area, the read method comprising:
shifting data stored at the reference area with a weighting scheme to read the shifted data;
generating a reference voltage based on the read data; and
reading data stored at the main area using the reference voltage.

13. The read method of claim 12, wherein the reference area is programmed using a same verification voltage as that of the main area.

14. The read method of claim 13, wherein the reference area is programmed at a same time with the main area.

15. The read method of claim 12, wherein a weight applied to shift data stored at the reference area is varied according to a time elapsing from a program operation on the reference cell.

16. The read method of claim 13, wherein the weight is varied in response to data stored at the reference area.
